(19) United States
(12) Patent Application Publication
(10) Pub. No.: US 2026/0262205 A1
(43) Pub. Date: Sep. 3, 2026

(54) Shielding enclosure for electronic equipment

(71) Applicant: KARL STORZ SE & Co. KG, Tuttlingen (DE)

(72) Inventors: Romana Geisser, Tuttlingen (DE); Matthias Weiss, Bad Dürrheim (DE)

(73) Assignee: KARL STORZ SE & Co. KG, Tuttlingen (DE)

(21) Appl. No.: 19/547,196

(22) Filed: Feb. 23, 2026

Related U.S. Application Data
(60) Provisional application No. 63/764,606, filed on Feb. 28, 2025.

(51) Int. Cl. H05K 9/00; H05K 5/02; H05K 5/03; H05K 5/04; H05K 5/13; H05K 5/15

(52) U.S. Cl. CPC H05K 9/0049; H05K 5/0243; H05K 5/03; H05K 5/04; H05K 5/13; H05K 5/15; H05K 9/0081

(57) ABSTRACT

One aspect is directed to an improved monolithic cover for an electronic device that is substantially free of fasteners and is at least partially based on a frictional engagement with another portion of an enclosure. A portion of the cover includes a plurality of metal fingers that exert a force that holds a complementary portion of the cover against another component of an enclosure of the electronic device, such as a lip of a bezel, such as a front or rear bezel. The exemplary cover is stainless steel, and a front portion of the cover includes the plurality of metal fingers that are offset relative to a main plane of the cover thereby defining a gap between a main plane of the cover and the offset metal fingers, wherein a lip of another cover is sandwiched and held in the gap.

### CROSS-REFERENCE TO RELATED APPLICATIONS

The present application claims the benefit of and priority, under 35 U.S.C. § 119(e), to U.S. Provisional Application Serial No63/764,606, filed on February 28, 2025, entitled “Shielding Enclosure for Electronic Device,” the entire disclosure of which is hereby incorporated herein by reference, in its entirety, for all that it teaches and for all purposes.

This application is also related to the following applications, which are filed herewith:

U.S. Provisional Application Serial No. 63/764,625, filed on February 28, 2025, entitled “Signal Adapter Device,”

U.S. Provisional Application Serial No. 63/764,609, filed on February 28, 2025, entitled “Cooling System for Electronic Devices,”

U.S. Provisional Application Serial No. 63/765,228, entitled “User Interface Navigation, Control, and Display,”

U.S. Provisional Application Serial No. 63/764,610, entitled “Electronic Device with Improved Circuit Board Holding System,”

U.S. Provisional Application Serial No. 63/764,612, entitled “Status Indicating Switch for Electrical Equipment, Especially Medical Equipment,”

U.S. Provisional Application Serial No. 63/764,615, entitled “Data Transfer System and Method for Image Processing,” and

U.S. Provisional Application Serial No. 63/764,614, entitled “Circuit Board Retaining Device,”

all of which are incorporated herein by reference in their entirety.

### BACKGROUND

The present disclosure is generally related to enclosures, or portions thereof, configured to provide EMC shielding.

EMC shielding is, generally speaking, any technology configured to protect signals, for example in an electronic device, from external electromagnetic signals/interference, and/or configured to prevent a signal from egressing from the electronic device causing interference with other surrounding electronic device(s) and/or the environment.

EMC stands for Electro Magnetic Compatibility, which means that a circuit/device/electronic component has the necessary components/configuration/construction to provide the shielding discussed above.

Unwanted electromagnetic energy can reap havoc on electronic devices, and especially sensitive electronic devices. This unwanted electromagnetic energy has the potential to create a wide variety of different issues from, for example, an induced hiss on a communication line, to a total disruption of mission or safety-critical signal(s). As such, this energy has the potential to impact a wide variety of industrial and consumer sectors, including but not limited to consumer electronics, industrial electronics, military electronics, medical electronics, and the like.

Standards that govern EMC shielding generally fall into two categories. The first are the IEC standards on Electromagnetic compatibility (EMC), which are mostly part of the IEC 61000 family. Some examples of these are IEC/TR EN 61000-1-1, Electromagnetic compatibility (EMC) - Part 1: General - Section 1: Application and interpretation of fundamental definitions and terms, IEC/TR EN 61000-2-1, Electromagnetic compatibility (EMC) - Part 2: Environment - Section 1: Description of the environment - Electromagnetic environment for low-frequency conducted disturbances and signaling in public power supply systems, etc.

The second is CISPR (Comité International Spécial des Perturbations Radio) or the International Special Committee for Radio Protection of IEC. CISPR Standards are generally directed to emissions in the 9 kHz to 400 GHz range and address interference caused by electronics. Many of the CISPR standards address product emissions and RF rejection requirements as well as provide testing methodologies for compliance.

### SUMMARY

The present disclosure is directed to an improved enclosure component.

Even more specifically, one aspect is directed to an improved cover for an electronic device.

Even more specifically, one aspect is directed to an improved cover for an electronic medical device.

Even more specifically, one aspect is directed to an improved cover for an electronic device that has a simplified construction and material composition.

Even more specifically, one aspect is directed to an improved monolithic cover for an electronic device that is substantially (or completely) free of fasteners and is at least partially based on a frictional engagement with another portion of an enclosure.

In accordance with one exemplary aspect, a portion of the cover includes a plurality of metal fingers that exert a force that holds a complementary portion of the cover against another component of an enclosure of the electronic device, such as a lip of a bezel, such as a front or rear bezel.

In accordance with one exemplary aspect, the cover is stainless steel, and a front portion of the cover includes a plurality of metal fingers that are offset relative to a main plane of the cover thereby defining a gap between a main plane of the cover and the offset metal fingers, wherein a lip of another cover is sandwiched and held in the gap.

The cover can optionally include further layers, such as decorative layer(s) affixed to at least one outside portion thereof, such as an outer surface. This decorative layer(s) can be affixed through any known means such as adhesive, rivets, screws, fasteners, molding, and/or any combination thereof.

The cover can optionally have the fingers one or more edges thereof, such as the front and back edges.

The exemplary cover exhibits high EMC shielding capabilities while avoiding some of the drawbacks of prior designs such as having multiple (separate) components which required assembly, requiring special coating(s), requiring multiple layers, requiring multiple material types and/or not providing adequate EMC shielding.

The preceding is a simplified summary of the disclosure to provide an understanding of some aspects of the disclosure. This summary is neither an extensive nor exhaustive overview of the disclosure and its various aspects, embodiments, and configurations. It is intended neither to identify key or critical elements of the disclosure nor to delineate the scope of the disclosure but to present selected concepts of the disclosure in a simplified form as an introduction to the more detailed description presented below. As will be appreciated, other aspects, embodiments, and configurations of the disclosure are possible utilizing, alone or in combination, one or more of the features set forth above or described in detail below.

Numerous additional features and advantages are described herein and will be apparent to those skilled in the art upon consideration of the following Detailed Description and in view of the accompanying figures.

### BRIEF DESCRIPTION OF THE DRAWINGS

The accompanying drawings are incorporated into and form a part of the specification to illustrate several examples of the present disclosure. These drawings, together with the description, illustrate exemplary principles of the disclosure. The drawings simply illustrate exemplary and alternative examples of how the disclosure can be made and used and are not to be construed as limiting the disclosure to only the illustrated and described examples. Further features and advantages will become apparent from the following, more detailed, description of the various aspects, embodiments, and configurations of the disclosure, as illustrated by the drawings referenced below.

It should be understood that the drawings are not necessarily to scale. In certain instances, details that are not necessary for an understanding of the disclosure or that render other details difficult to perceive may have been omitted. It should be understood, of course, that the disclosure is not necessarily limited to the particular embodiments illustrated herein.

FIG. 1 illustrates an exemplary enclosure in accordance with aspects of the present disclosure.

FIG. 2 illustrates a top-front perspective view of an exemplary cover in accordance with aspects of the present disclosure.

FIG. 3 illustrates a top, upper right-hand side perspective view of an exemplary cover in accordance with aspects of the present disclosure.

FIG. 4 illustrates an exploded view of a portion of FIG. 3 in accordance with aspects of the present disclosure.

FIG. 5 illustrates an exploded view of a portion of FIG. 3 in accordance with aspects of the present disclosure.

FIG. 6 illustrates a bottom view of an exemplary cover in accordance with aspects of the present disclosure.

FIG. 7 illustrates an exploded view of a portion of FIG. 6 in accordance with aspects of the present disclosure.

FIG. 8 illustrates an exploded partial view from FIG. 5 in accordance with aspects of the present disclosure.

FIG. 9 illustrates a side view of the cover and front bezel engagement in accordance with aspects of the present disclosure.

FIG. 10 illustrates another side (partial cross-section) wire-frame view of the cover and front bezel engagement of FIG. 9 in accordance with aspects of the present disclosure.

FIG. 11 illustrates a rear perspective view of an exemplary cover in accordance with aspects of the present disclosure.

FIG. 12 illustrates a rear perspective view of an exemplary cover engaged with a back cover in accordance with aspects of the present disclosure.

FIG. 13 illustrates exemplary dimensions of some of the components in accordance with certain, non-limiting, aspects of the present disclosure.

### DETAILED DESCRIPTION

Before any embodiments of the disclosure are explained in detail, it is to be understood that the disclosure is not limited in its application to the details of construction and the arrangement of components set forth in the following description or illustrated in the drawings. The disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Further, the present disclosure may use examples to illustrate one or more aspects thereof. Unless explicitly stated otherwise, the use or listing of one or more examples (which may be denoted by “for example,” “by way of example,” “e.g.,” “such as,” or similar language) is not intended to and does not limit the scope of the present disclosure.

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

Various aspects of the present disclosure will be described herein with reference to drawings that may be schematic illustrations of idealized configurations.

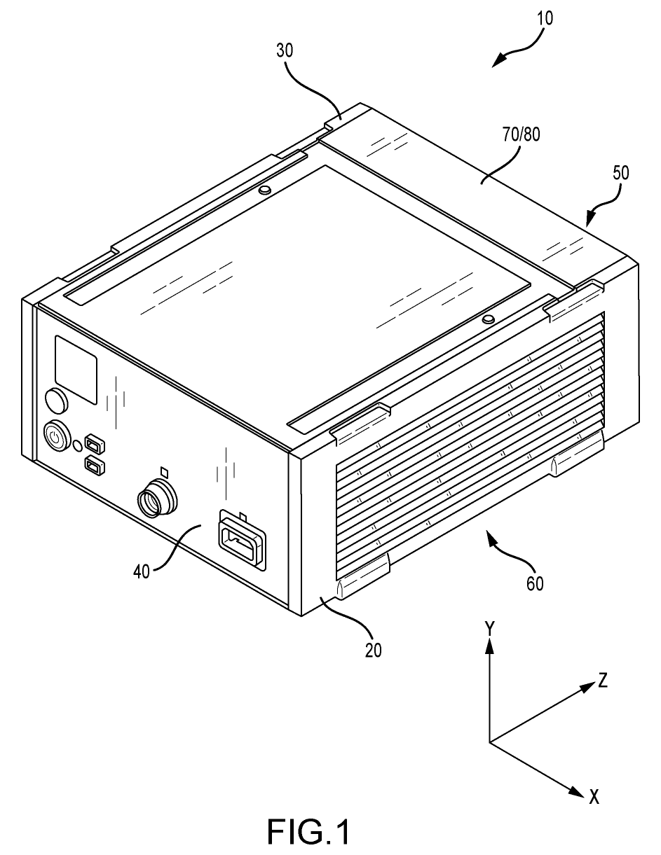

FIG. 1 illustrates an exemplary enclosure in accordance with aspects of the present disclosure. The enclosure 10 includes a right-hand side cover 20, a left-hand side cover 30, a front bezel 40, a rear bezel 50 (not shown), a bottom cover 60 (not shown) and a top cover optionally comprised of multiple parts including an outer top cover portion 70 and an inner top cover portion 80.

It is to be appreciated that one or more of the covers and bezels of the enclosure 10 can be singular components, and/or multiple components. For example, in illustrative FIG. 1, the top cover optionally includes a decorative outer top cover 70 over the inner primary EMC shielding inner top cover 80. Here the exemplary inner top cover 80 is made of stainless steel, but other electromagnetic shielding materials can also be used such as, but not limited to: metals (e.g., copper, copper alloy, aluminum, plated metals, plated steel, nickel, monel, Mu-metal, or the like), alloys, polymer carbon composites, polymer ceramic composites, graphene, graphite, and the like.

The inner top cover 80, as described herein, engages with the other covers/bezels of the enclosure 10 to create an EMC shielded enclosure for electronic equipment, such as medical equipment. It is to be appreciated that various covers/bezels can be attached to one another using various means such as fasteners, adhesives, rivets, screws, bolts/nuts, or in general using any known technique or methodology. Additionally, the general construction and configuration of the inner top cover 80 is not limited thereto, and in general the exemplary configuration with fingers could be used with any one or more of the covers/bezels on any one or more of the edges thereof.

However, one of the exemplary advantages of the exemplary inner top cover 80 is that the fingers 90 not only ease assembly through a simple slide-to-fit connection, but also sandwich a portion of the front bezel between the fingers and a main portion of the inner top cover 70, with this snug fit facilitating electromagnetic shielding. Another exemplary advantage is that the choice of stainless steel for the inner top cover 80, with its strength characteristics, allows the length of the fingers to be shortened thereby reducing the gap/spacing around each of the finger cut-outs. This again helps with electromagnetic shielding as areas with no metal through which electromagnetic radiation can escape are reduced. Yet another exemplary advantage is that the inner top cover 80 and fingers 90 can all be made from the same piece of stainless steel, with the fingers stamped therefrom and die cut/bent into the general shape illustrated herein that again facilitates ease of manufacturing, assembly and securing of the front bezel therein.

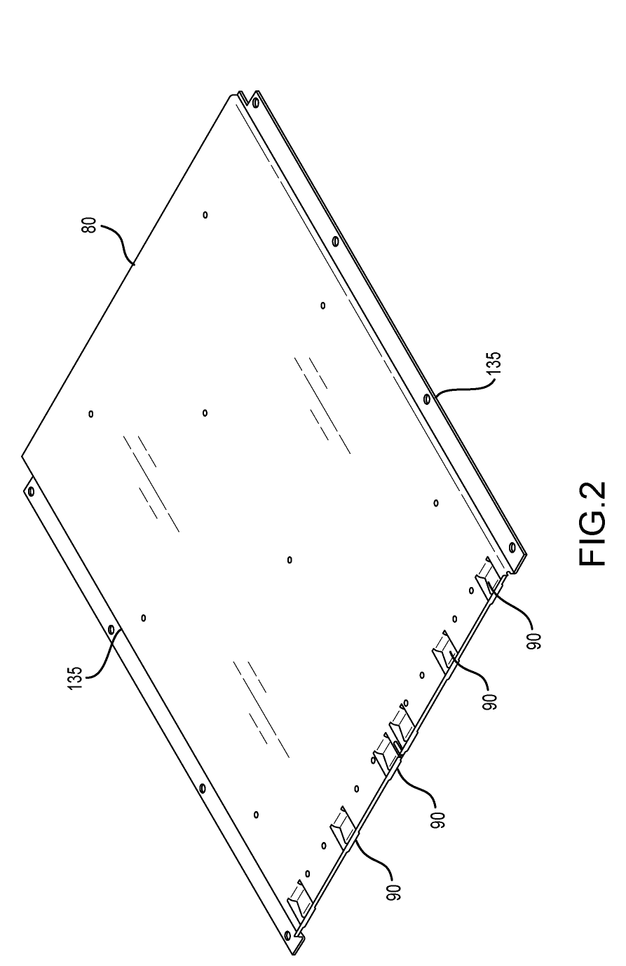

FIG. 2 illustrates a top-front perspective view of an exemplary cover in accordance with aspects of the present disclosure. In FIG. 2, it can be seen that there are 6 exemplary fingers 90, with of course any number of fingers capable of being pressed into the inner top cover 80. Also shown is an exemplary screw hole(s) 135 to allow optional connection, via a fastener, of the inner top cover 80 to another portion of the enclosure 10.

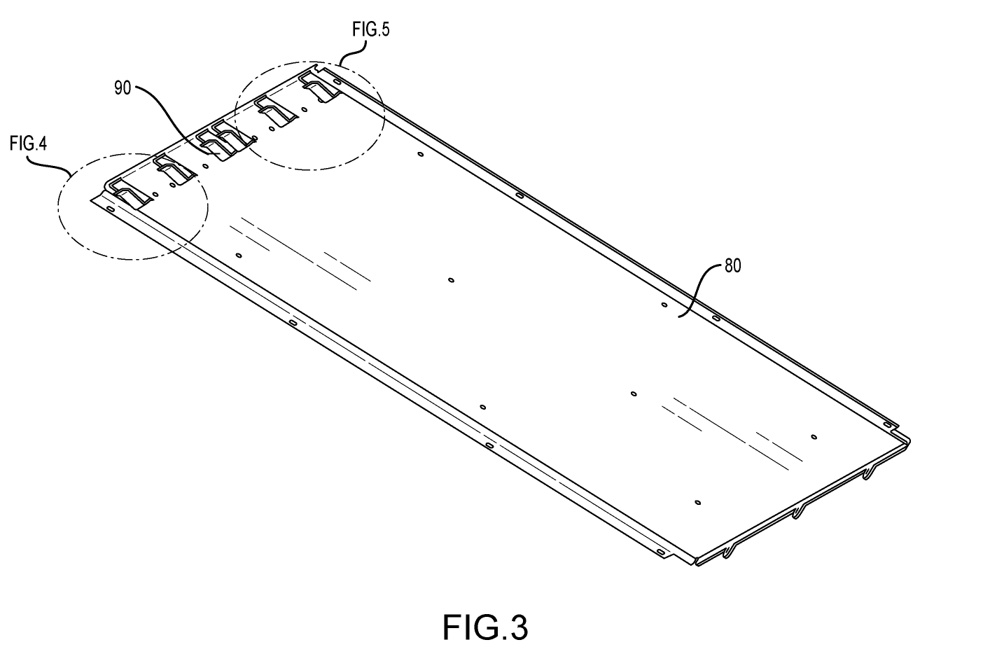

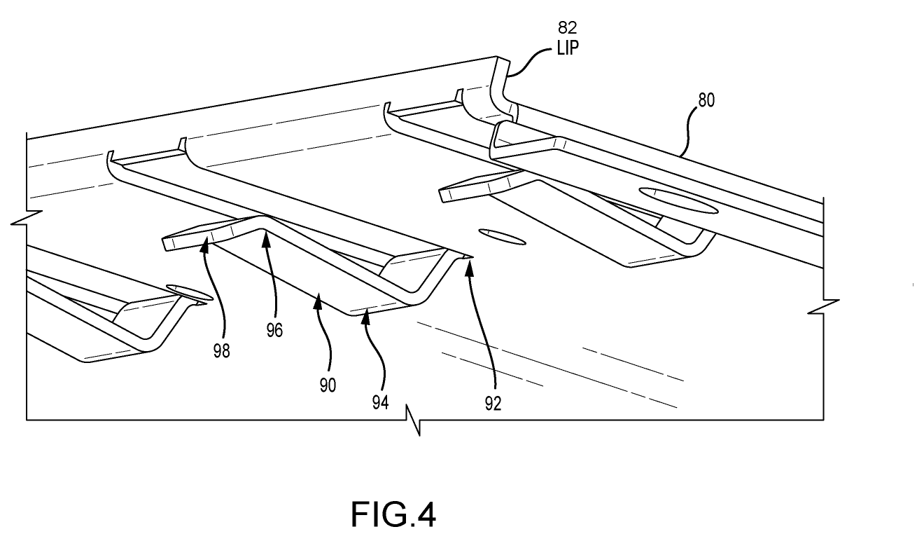

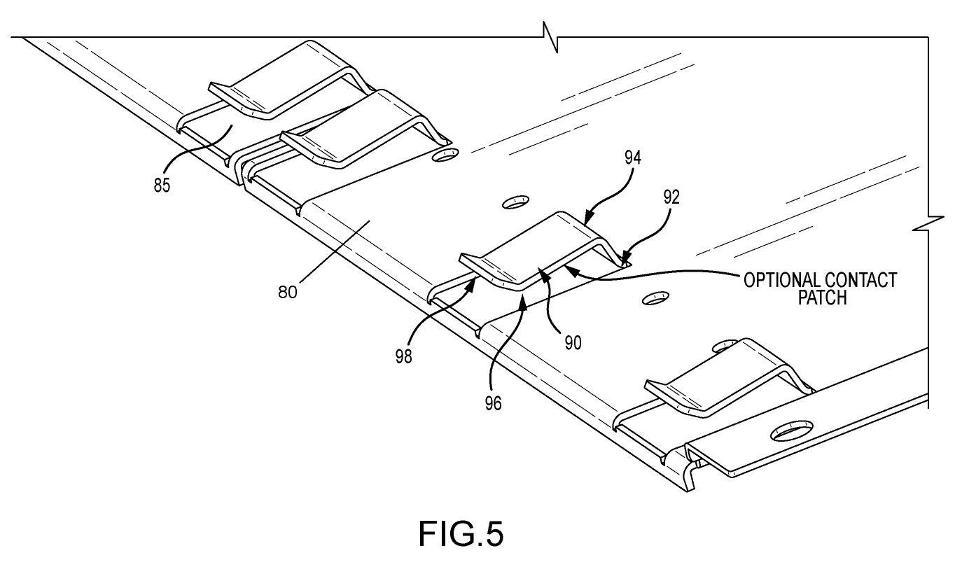

FIG. 3 illustrates a top, upper right-hand side perspective view of an exemplary cover in accordance with aspects of the present disclosure. In this view, the inner top cover 80 shows another angle of the fingers 90, with zoomed-in portions illustrated hereinafter in FIGS. 4 and 5.

In FIG. 3, the exemplary inner top cover 80 can be seen with step-down sides and rear cover screw tabs, with all of these features of course being optional. Depending on the specific configuration of the enclosure, other designs are possible that facilitate interconnection of the various components as is well within the skill of a person of ordinary skill in the art.

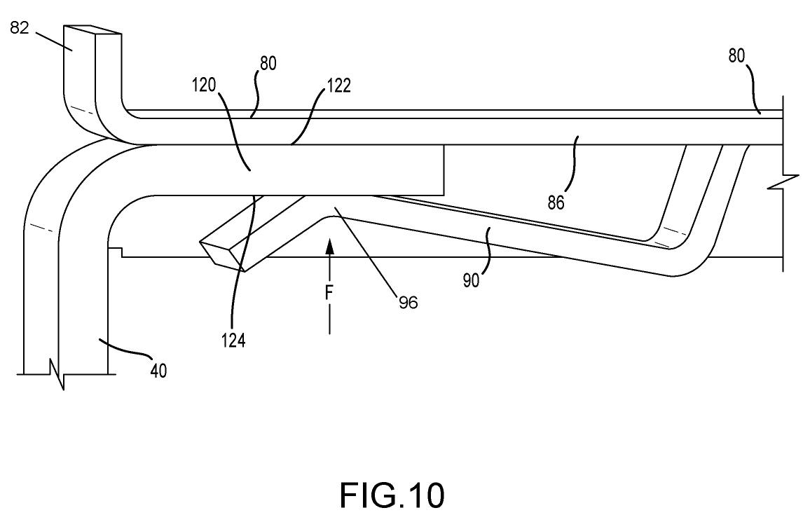

FIG. 4 illustrates an exploded solid view from FIG. 3 in accordance with aspects of the present disclosure. Here, the die-pressed configuration of the fingers is shown. The exemplary fingers 90 each include a finger base 92, a finger first knee 94, a finger second knee 96 and a finger front lip (or bevel) 98. The formation and die pressing of the fingers results in a gap 85 (discussed hereinafter as receiving the lip from the front bezel) as well as a cut-out 100 (Seen better in FIG. 10) from the base material of the inner top cover 80 where the fingers were stamped. The formation of the fingers 90 and subsequent die stamping creates a spring tension as the fingers are moved to increase the size of the gap 85. This tension helps eliminate any space between the bottom surface 86 of the inner top cover 80 and a top surface 122 of the lip of the front bezel 40 (as shown in FIG. 10), and between the bottom surface 124 of the lip of the front bezel 40 and the surface 88 of finger second knee 96.

As shown in FIG. 4, the exemplary fingers 90 each include a finger base 92, a finger first knee 94, a finger second knee 96 and a finger front lip (or bevel) 98. While exemplary angles and configurations are shown for these fingers, it is to be appreciated that deviations from these dimensions/angles are certainly possible while still maintaining the overall functionality discussed herein. As just some examples, the fingers could be wider, narrower, longer, shorter, and/or have a different shape when viewed in cross-section or plan view provided the shielding and receiving of the front bezel functionality are maintained.

Similarly, the front lip 98 could alternatively or in addition be more horizontal and (more or completely) aligned with the plane along the x-z-axis of the large portion of the inner top cover 80 with a chamfer, bezel, and/or radius, or the like.

Optionally, the inner top cover 80 could also include a lip 82 (that extends upward or downward) on the front face configured to abut the front bezel. (Shown in FIG. 10 extending upward.)

FIG. 5 illustrates an exploded solid view from FIG. 3 of the bottom front of the inner top cover 80 in accordance with aspects of the present disclosure.

The spring tension to hold the lip of the front bezel is primarily present at the finger base 92. While in one embodiment the underside of the second knee 96 is the primary portion that comes into contact with the lip of the front bezel, it is to be appreciated that the angles of the finger could be varied (primarily the angle of the first knee 94) such that more of less of the optional contact patch (on the underside of the finger 90) shown in FIG. 5 could come into contact with the lip of the front bezel.

Optionally or in addition, the edge of the front bezel could abut against the finger base, which may serve as a stopper when pushing the top cover onto the bezel. This may help with positioning of the top cover. Similarly, the front tip of the finger could abut the front bezel for positioning.

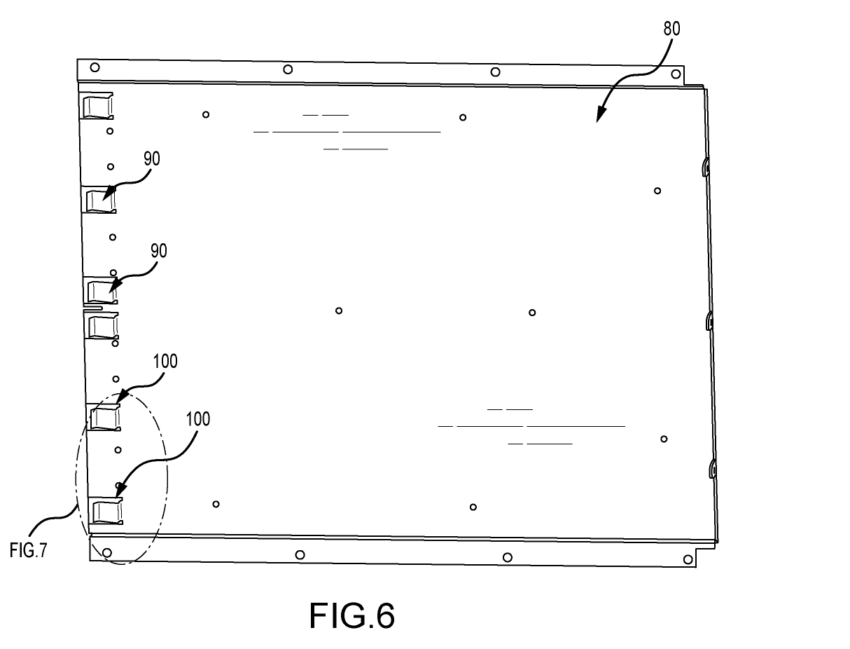

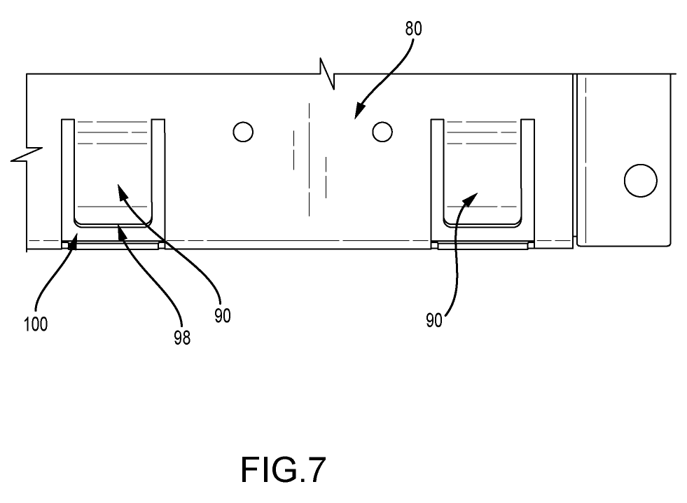

FIG. 6 illustrates a bottom plan view of an exemplary cover in accordance with aspects of the present disclosure. In this view, as well as in FIG. 7 the cutout around each of the fingers 90 is more clearly visible. While this cutout 100 is shown with certain spacing around the fingers 90, it is to be appreciated that the dimensions and clearances of this cutout can be varied to create either more or less space around the fingers, and the spaces around each finger do not need to be the same.

FIG. 7 illustrates an exploded view from FIG. 6 in accordance with aspects of the present disclosure. The finger cutout 100 is more clearly seen in these views. While the fingers 90 are shown not extending fully to the front edge of the inner top cover 80, it is to be appreciated, as discussed, that the length of the fingers 90 can be varied and could extend to the front edge of the inner top cover 80. Exemplary design considerations for the length of the fingers 90 could be one or more of: holding force, material strengths, assembly factors, number of fingers, and the like.

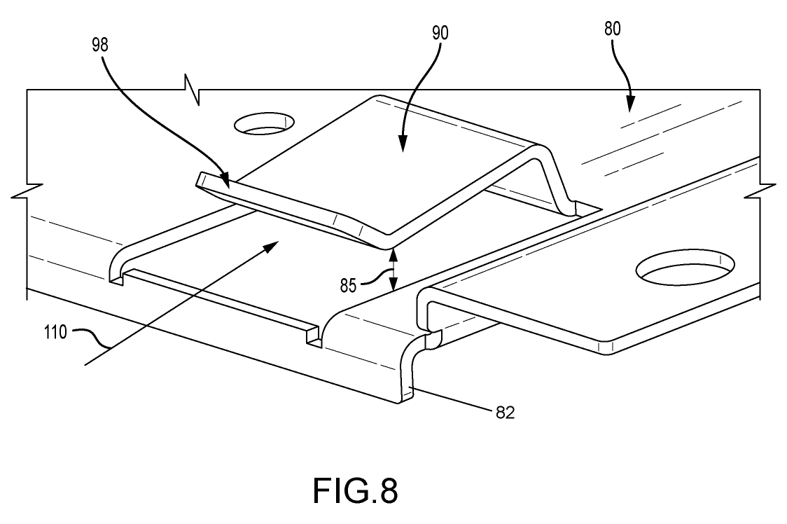

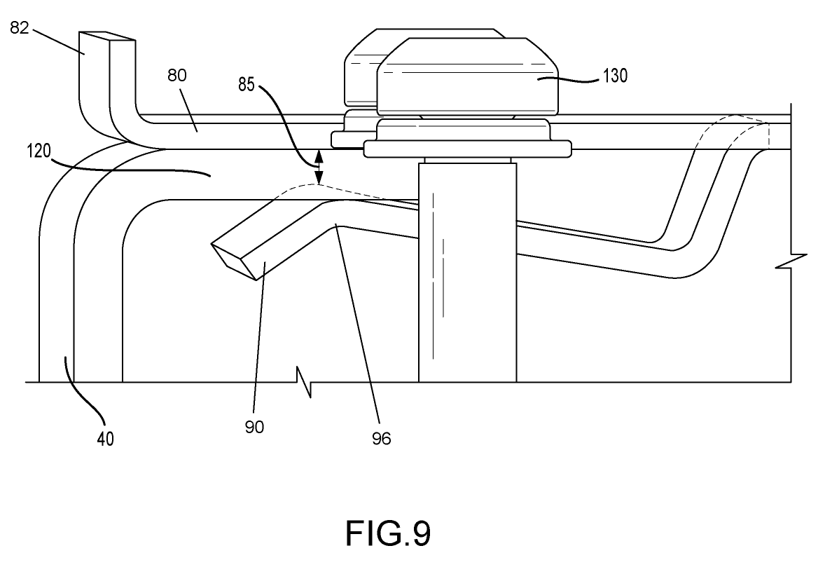

Regarding assembly, FIG. 8 illustrates an exploded partial view from FIG. 6 in accordance with aspects of the present disclosure. In FIG. 8, the insertion direction 110 for the lip of the front bezel is shown. As discussed, the lip of the front bezel (shown assembled in FIGS. 9-10) is slid between the underside of the inner top cover 80 and under the second knee 96 into gap 85. Optionally, the lip of the front bezel is slid substantially to the rear of the finger 90 adjacent to the finger base 92.

FIG. 9 illustrates an exemplary engagement between the cover and a front bezel viewed from the left back under-side in accordance with aspects of the present disclosure. In FIG. 9, the front bezel lip 120 has been installed/inserted into the inner top cover 80 and secured by the fingers. Of note, this exemplary configuration does not require any fasteners. However, optional fasteners and/or adhesive(s) could be added during the assembly process,

The front bezel lip 120 can be seen sandwiched between the bottom of the inner top cover 80 and the finger(s) 90. Of note, in this exemplary embodiment, there is little to no gap between the surface of the front bezel lip 120 that contacts the underside of the inner top cover 80 in the areas where there are no cutouts for the fingers 90. As discussed, this helps improve the shielding characteristics of the enclosure 10.

FIG. 9 illustrates a side view of the cover and front bezel engagement in accordance with aspects of the present disclosure. FIG. 10. illustrates another side (partial cross-section) wire-frame view of the cover and front bezel engagement in accordance with aspects of the present disclosure.

In FIGS. 9-10, the gap 85 has been filled by the front bezel lip 120, deflecting the fingers 90 thereby frictionally sandwiching the front bezel lip 120 in the inner top cover 80. Optional fasteners 130 are shown that can be used to secure the side(s)s of the inner top cover 80 to the side covers via fastener holes 135 (Seen in FIG. 2). A snug fit can be achieved and space between the bottom surface 86 of the inner top cover 80 and a top surface 122 of the lip of the front bezel 40 virtually eliminated due to the tension (shown by force arrow F) applied by the fingers 90 on the bottom surface 124 of the lip of the front bezel 40 and the surface 88 of finger second knee 96.

FIG. 10 further illustrates a side view of the cover and front bezel engagement of FIG. 9 in accordance with aspects of the present disclosure. Here, the front bezel lip 120 only extends partially to the back of the finger slot, but, as discussed, the length of the front bezel lip could be adjusted to extend any amount underneath the fingers 90. Similarly, the depth/length of the fingers could be altered to change the extent of engagement with the front bezel lip.

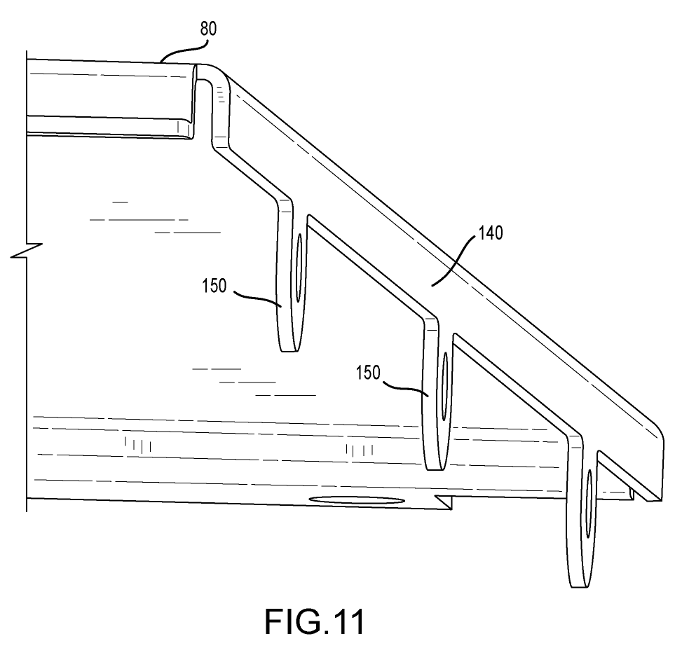

FIG. 11 illustrates a rear perspective view of an exemplary cover in accordance with aspects of the present disclosure. The inner top cover 80 can optionally further include a back lip 140 with one or more screw (or comparable) tabs 150. The addition of fasteners to the screw tabs can assist with pushing the lip of the front bezel into the inner top cover 80 when the enclosure 10 is fully assembled. Alternatively, the lip 140 can be a solid piece (instead of screw tabs) extending substantially across the rear of the cover and can include one or more fastener holes.

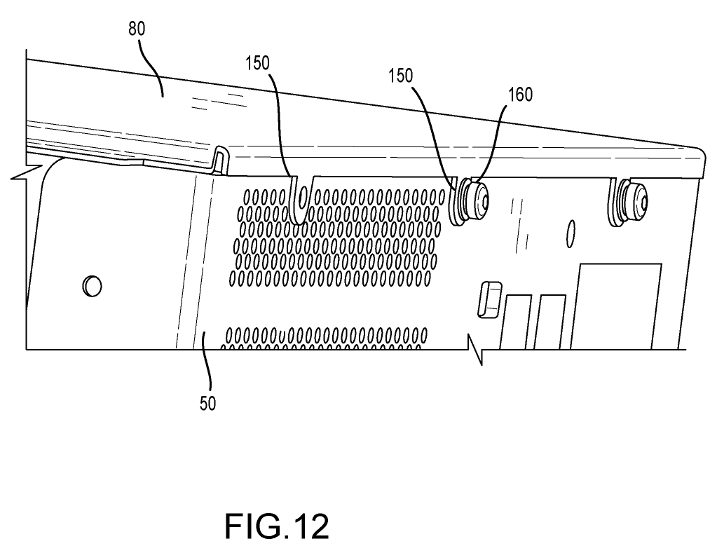

FIG. 12 illustrates a rear perspective view of an exemplary cover engaged with a back cover in accordance with aspects of the present disclosure.

Specifically, FIG. 12 shows a partially assembled state where the inner top cover 80 has been placed over the rear bezel 50, and the two parts have been secured with fasteners 160. While not shown, the rear bezel 50 can be made from the same piece of material as the bottom cover thereby forming a chassis onto which the front bezel, top cover(s), rear bezel and side covers are attached.

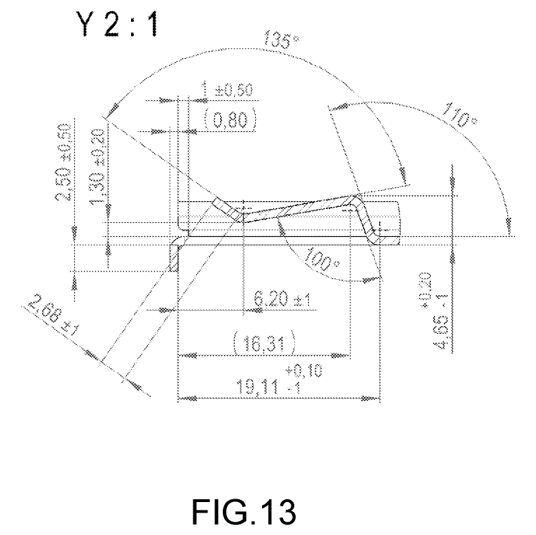

In accordance with one exemplary, non-limiting, embodiment of a cover of a shielding enclosure comprising one or more fingers, the dimensions (in mm) and angles of the various components are shown in FIG. 13.

Alternatively, while the enclosure is shown having the front bezel engage on a specific side of the cover, it is to be appreciated that the front bezel could engage on the opposite side of the cover with the fingers being on an “outside” instead of the “inside” of the enclosure.

Any of the steps, functions, and operations discussed herein can be performed continuously and/or automatically.

While the steps have been discussed and illustrated in relation to a particular sequence of events, it should be appreciated that changes, additions, and omissions to this sequence can occur without materially affecting the operation of the disclosed embodiments, configuration, and aspects.

Although the figures are largely shown in solid lines, it should be understood that one or more aspects of the enclosure 10 may not form part of the claimed invention or design but rather is only a portion of an environment surrounding the claimed invention or design and/or a portion of an environment in which the claimed invention or design operates. In one non-limiting example, any or all of the covers other than inner top cover 80 may not form part of the claimed invention or design but rather is only a portion of an environment surrounding the claimed invention or design and/or a portion of an environment in which the claimed invention or design operates. Therefore, the description through the present disclosure should not be interpreted as a limitation on the scope of the present disclosure but merely an illustration.

The exemplary systems and methods of this disclosure have been described in relation to an enclosure. However, to avoid unnecessarily obscuring the present disclosure, the preceding description may omit a number of known structures and devices. This omission is not to be construed as a limitation of the scope of the claimed disclosure. Specific details are set forth to provide an understanding of the present disclosure. It should, however, be appreciated that the present disclosure may be practiced in a variety of ways beyond the specific detail set forth herein.

A number of variations and modifications of the disclosure can be used. It would be possible to provide for some features of the disclosure without providing others. In addition, it would be possible to combine some features of the disclosure without combining all.

References in the specification to “being operable” or “is operable” may be understood as “being configured to” or “is configured to, “being capable of” or “is capable of,” and the like.

References in the specification to “an aspect,” “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in conjunction with one embodiment, it is submitted that the description of such feature, structure, or characteristic may apply to any other embodiment unless so stated and/or except as will be readily apparent to one skilled in the art from the description. The present disclosure, in various embodiments, configurations, and aspects, includes components, methods, processes, systems and/or apparatus substantially as depicted and described herein, including various embodiments, sub-combinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

Exemplary aspects are directed toward:

A shielding enclosure for electronic equipment comprising:

a cover;

the cover having at least four sides, one or more of the four sides including one or more fingers, wherein each of the fingers:

includes a base connected with the cover and a front portion,

are cut on three sides from the cover, and

are configured to frictionally engage through tension a portion of another cover of the enclosure between the cover and each of the fingers.

Any of the above aspects, wherein the another cover is a bezel, and the bezel includes a lip that extends into a gap present between each of the fingers and an underside of the cover.

Any of the above aspects, wherein each of the fingers include a base area and a front edge.

Any of the above aspects, wherein each of the fingers further include a chamfer, a ramp and/or a bevel on the front edge.

Any of the above aspects, wherein each of the fingers further include one or more of a first knee and a second knee bent at respective angles.

Any of the above aspects, wherein a space exists on three sides of the fingers when the cover is viewed in plan view.

Any of the above aspects, wherein a tension force is exerted by each of the fingers to secure a lip of the another cover between the cover and each of the fingers.

Any of the above aspects, wherein the fingers are die cut.

Any of the above aspects, wherein at least a portion of a side of each of the fingers, in an assembled state, is in contact with a lip of the another cover.

Any of the above aspects, wherein at least a portion of an underside of the cover adjacent to each of the fingers, in an assembled state, is in contact with a lip of the another cover.

Any of the above aspects, comprising multiple covers.

Any of the above aspects, wherein the enclosure is configured to provide electromagnetic shielding.

Any of the above aspects, further comprising one or more of screw tabs and fastener holes configured to secure the cover to one or more other portions of the enclosure.

Any of the above aspects, further comprising one or more of a front lip and a back lip on the cover.

Any of the above aspects, further comprising a chassis, wherein two or more sides of the enclosure are made from the same piece of material.

Any of the above aspects, wherein the cover is stainless steel.

Any of the above aspects, wherein the fingers are approximately 15mm in overall length.

Any of the above aspects, further comprising a decorative cover attached to an outer surface of the cover.

Any of the above aspects, wherein the fingers are formed in the cover and integral thereto.

Any of the above aspects, wherein each of the fingers are bent to form a spring tension upon insertion of another component between the fingers and an underside of the cover.

Any one or more of the above aspects/embodiments as substantially disclosed herein.

Any one or more of the aspects/embodiments as substantially disclosed herein optionally in combination with any one or more other aspects/embodiments as substantially disclosed herein.

One or means adapted to perform any one or more of the above aspects/embodiments as substantially disclosed herein.

Any one or more of the features disclosed herein.

Any one or more of the features as substantially disclosed herein.

Any one or more of the features as substantially disclosed herein in combination with any one or more other features as substantially disclosed herein.

Any one of the aspects/features/embodiments in combination with any one or more other aspects/features/embodiments.

Use of any one or more of the aspects or features as disclosed herein.

It is to be appreciated that any feature described herein can be claimed in combination with any other feature(s) as described herein, regardless of whether the features come from the same described embodiment.

As used herein, the singular forms “a,” “an,” and “the” are intended to include the plural forms as well, unless the context clearly indicates otherwise. It will be further understood that the terms “include,” “including,” “includes,” “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items. The use of “including,” “comprising,” or “having” and variations thereof herein is meant to encompass the items listed thereafter and equivalents thereof as well as additional items. Accordingly, the terms “including,” “comprising,” or “having” and variations thereof can be used interchangeably herein.

The transitional phrase “consisting of” excludes any element, step, or ingredient not specified in the claim, but does not exclude additional components or steps that are unrelated to the disclosure such as impurities ordinarily associated therewith. The transitional phrase “consisting essentially of” limits the scope of a claim to the specified materials or steps and those that do not materially affect the basic and novel characteristic(s) of the claimed invention.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” and “A, B, and/or C” means A alone, B alone, C alone, A and B together, A and C together, B and C together, or A, B, and C together. When each one of A, B, and C in the above expressions refers to an element, such as X, Y, and Z, or a class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

The term “automatic” and variations thereof, as used herein, refers to any process or operation, which is typically continuous or semi-continuous, done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The terms “determine,” “calculate,” “compute,” and variations thereof, as used herein, are used interchangeably and include any type of methodology, process, mathematical operation, or technique.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

Unless otherwise indicated, all numbers expressing quantities, dimensions, conditions, ratios, ranges, and so forth used in the specification and claims are to be understood as being modified in all instances by the term “about” or “approximately.” Accordingly, unless otherwise indicated, all numbers expressing quantities, dimensions, conditions, ratios, ranges, and so forth used in the specification and claims may be increased or decreased by approximately 5% to achieve satisfactory results. Additionally, where the meaning of the terms “about” or “approximately” as used herein would not otherwise be apparent to one of ordinary skill in the art, the terms “about” and “approximately” should be interpreted as meaning within plus or minus 5% of the stated value.

All ranges described herein may be reduced to any sub-range or portion of the range, or to any value within the range without deviating from the invention. For example, the range “5 to 55” includes, but is not limited to, the sub-ranges “5 to 20” as well as “17.5 to 54.8,” as well as any and all other subranges therein.

It should be understood that every maximum numerical limitation given throughout this disclosure is deemed to include each and every lower numerical limitation as an alternative, as if such lower numerical limitations were expressly written herein. Every minimum numerical limitation given throughout this disclosure is deemed to include each and every higher numerical limitation as an alternative, as if such higher numerical limitations were expressly written herein. Every numerical range given throughout this disclosure is deemed to include each and every narrower numerical range that falls within such broader numerical range, as if such narrower numerical ranges were all expressly written herein.

For ease of discussion, the various elements of the exemplary embodiments have been labeled as follows:

10 – Enclosure

20 – Right-Hand Side Cover

30 – Left-Hand Side Cover

40 – Front Bezel

50 – Rear Bezel

60 – Bottom Cover

70 – Outer Top Cover

80 – Inner Top Cover

82 – lid

85 – Gap

86 - bottom surface

90 – Finger

92 – Finger Base

94 – Finger first Knee

96 – Finger Second Knee

98 – Finger Front Lip

100 – Finger Cut Out

110 – Insertion Direction for Front Bezel

120 – Front Bezel Lip

130 – Fastener

140 – Rear Cover Lip

150 – Rear Cover Screw Tab

160 – Fastener

What is claimed is:

1. A shielding enclosure for electronic equipment comprising:
a cover;
the cover having at least four sides, one or more of the four sides including one or more fingers, wherein each of the fingers:
includes a base connected with the cover and a front portion,
are cut on three sides from the cover, and
are configured to frictionally engage through tension a portion of another cover of the enclosure between the cover and each of the fingers.

2. The enclosure of claim 1, wherein the another cover is a bezel, and the bezel includes a lip that extends into a gap present between each of the fingers and an underside of the cover.

3. The enclosure of claim 1, wherein each of the fingers include a base area and a front edge.

4. The enclosure of claim 3, wherein each of the fingers further include a chamfer, a ramp and/or a bevel on the front edge.

5. The enclosure of claim 3, wherein each of the fingers further include one or more of a first knee and a second knee bent at respective angles.

6. The enclosure of claim 1, wherein a space exists on three sides of the fingers when the cover is viewed in plan view.

7. The enclosure of claim 1, wherein a tension force is exerted by each of the fingers to secure a lip of the another cover between the cover and each of the fingers.

8. The enclosure of claim 1, wherein the fingers are die cut.

9. The enclosure of claim 1, wherein at least a portion of a side of each of the fingers, in an assembled state, is in contact with a lip of the another cover.

10. The enclosure of claim 1, wherein at least a portion of an underside of the cover adjacent to each of the fingers, in an assembled state, is in contact with a lip of the another cover.

11. The enclosure of claim 1, comprising multiple covers.

12. The enclosure of claim 1, wherein the enclosure is configured to provide electromagnetic shielding.

13. The enclosure of claim 1, further comprising one or more of screw tabs and fastener holes configured to secure the cover to one or more other portions of the enclosure.

14. The enclosure of claim 1, further comprising one or more of a front lip and a back lip on the cover.

15. The enclosure of claim 1, further comprising a chassis, wherein two or more sides of the enclosure are made from the same piece of material.

16. The enclosure of claim 1, wherein the cover is stainless steel.

17. The enclosure of claim 1, wherein the fingers are approximately 15mm in overall length.

18. The enclosure of claim 1, further comprising a decorative cover attached to an outer surface of the cover.

19. The enclosure of claim 1, wherein the fingers are formed in the cover and integral thereto.

20. The enclosure of claim 1, wherein each of the fingers are bent to form a spring tension upon insertion of another component between the fingers and an underside of the cover.
